(19) United States
(12) Patent Application Publication
(10) Pub. No.: US 2023/0130684 A1
(43) Pub. Date: Apr. 27, 2023

(54) SEMICONDUCTOR DEVICE AND METHOD FOR FABRICATING THE SAME

(71) Applicant: SK hynix Inc., Gyeonggi-do (KR)

(72) Inventors: Se Ra HWANG, Gyeonggi-do (KR); Jun Sik Kim, Gyeonggi-do (KR)

(21) Appl. No.: 17/729,119

(22) Filed: Apr. 26, 2022

(30) Foreign Application Priority Data
Oct. 26, 2021 (KR) 10-2021-0143733

(51) Int. Cl. H01L 21/768; H01L 23/522; H01L 23/532

(52) U.S. Cl. CPC H01L 21/7682; H01L 23/5226; H01L 23/5329; H01L 27/10814

(57) ABSTRACT

A semiconductor device includes: a plurality of metal interconnections spaced apart over a substrate including a lower structure; a first hydrogen-containing layer covering the plurality of the metal interconnections; a dielectric layer formed over the first hydrogen-containing layer; an air gap formed between neighboring metal interconnections inside the dielectric layer; and a second hydrogen-containing layer formed over the dielectric layer.

### CROSS-REFERENCE TO RELATED APPLICATIONS

The present application claims priority of Korean Patent Application No. 10-2021-0143733, filed on Oct. 26, 2021, which is incorporated herein by reference in its entirety.

### BACKGROUND

### 1. Field

Various embodiments of the present invention relate generally to semiconductor technology, and more particularly, to a method for fabricating a semiconductor device.

### 2. Description of the Related Art

A typical semiconductor fabrication process requires one or more etching operations which may damage various semiconductor surfaces including semiconductor substrate surfaces. As the degree of integration of semiconductor devices increases, and spacing between various patterns becomes smaller, the likelihood of such phenomena occurring also increases. Hence, a number of dangling silicon bonds may form on a semiconductor substrate and may provide a source of leakage current, such as, for example, leakage current in a transistor.

New methods and structures are therefore needed to address these issues associated with existing semiconductor device technology.

### SUMMARY

Embodiments of the present invention are directed to a semiconductor device with improved leakage current characteristics, and a method for fabricating the semiconductor device.

In accordance with an embodiment of the present invention, a semiconductor device includes: a plurality of metal interconnections spaced apart over a substrate including a lower structure; a first hydrogen-containing layer covering the plurality of the metal interconnections; a dielectric layer formed over the first hydrogen-containing layer; an air gap formed between neighboring metal interconnections inside the dielectric layer; and a second hydrogen-containing layer formed over the dielectric layer.

In accordance with another embodiment of the present invention, a semiconductor device includes: a plurality of metal interconnections that are spaced apart over a substrate including a lower structure; a first hydrogen-containing layer covering the plurality of the metal interconnections; a dielectric layer formed over the first hydrogen-containing layer between the metal interconnections and including an air gap; and a second hydrogen-containing layer formed over the dielectric layer and the first hydrogen-containing layer.

In accordance with yet another embodiment of the present invention, a method for fabricating a semiconductor device includes: forming a plurality of metal interconnections spaced apart over a substrate including a lower structure; forming a first hydrogen-containing layer which covers the plurality of the metal interconnections; forming a dielectric layer including an air gap over the first hydrogen-containing layer; and forming a second hydrogen-containing layer over the dielectric layer.

### BRIEF DESCRIPTION OF THE DRAWINGS

FIG. 1 is a cross-sectional view illustrating a semiconductor device in accordance with an embodiment of the present invention.

FIGS. 2 to 5 are cross-sectional views illustrating semiconductor devices in accordance with other embodiments of the present invention.

FIGS. 6A to 6D are cross-sectional views illustrating a method for fabricating a semiconductor device in accordance with an embodiment of the present invention.

FIGS. 7A to 7C are cross-sectional views illustrating another example of a method for fabricating a semiconductor device in accordance with an embodiment of the present invention.

### DETAILED DESCRIPTION

Various embodiments of the present invention will be described below in more detail with reference to the accompanying drawings. The present invention may, however, be embodied in different other forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

As the patterns of the semiconductor device are miniaturized and interconnections are stacked, the problem of dark current may be exacerbated. The dark current is charges that are accumulated without the application of a voltage, and may be caused by defects or dangling bonds existing in a substrate. A dangling bond is a defect that may occur on the surface of a substrate when the substrate is subjected to an oxidation process, an etching process, or the like. A dangling bond may refer to a bond state in which the outermost peripheral electrons of atoms on the surface of a substrate do not form a perfect bond but are cut off. Electrons may be generated from the dangling bonds that are formed on the surface of a substrate and diffused into a device region. The device region may therefore be in a state where electric charges are readily generated even when no voltage is applied. If there is a large amount of dangling bonds on the substrate, a large number of charges may be generated even though no voltage is applied, and this makes the substrate react as if a voltage is applied thereto, showing abnormal operations such as noise or dark current. Therefore, it would be desirable to reduce or eliminate the dangling bonds from the substrate. According to an embodiment of the present invention, dangling bond defects may be resolved by bonding them with hydrogen. Therefore, a sufficient supply of hydrogen is provided into the substrate for removing the dangling bond defects from the surface of the substrate.

In the described embodiment of the present invention, the hydrogen passivation effect is maximized by additionally forming a hydrogen supply source which is in direct contact with the metal interconnections serving as hydrogen paths.

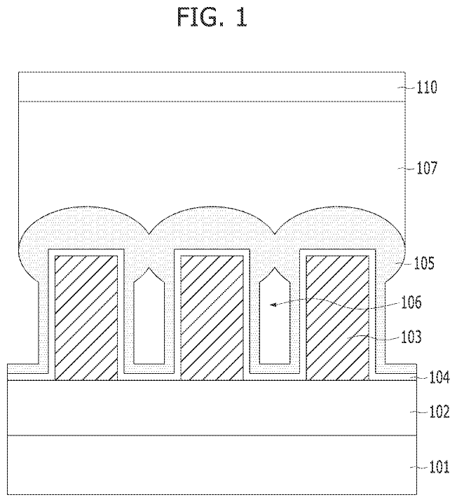

FIG. 1 is a cross-sectional view illustrating a semiconductor device in accordance with an embodiment of the present invention.

Referring to FIG. 1, the semiconductor device may include a substrate 101, a lower structure 102 formed over the substrate 101, metal interconnections 103 formed over the lower structure 102, air gaps 106 formed between the metal interconnections 103, a first hydrogen-containing layer 104 covering the metal interconnections 102, a dielectric layer 105 over the first hydrogen-containing layer 104, and a second hydrogen-containing layer 107 over the dielectric layer 105.

The substrate 101 may be a material suitable for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may include other semiconductor materials, such as germanium. The substrate 101 may include a III/V-group semiconductor substrate, for example, a compound substrate, such as gallium arsenide (GaAs). The substrate 101 may include a Silicon-On-Insulator (SOI) substrate.

The lower structure 102 may be formed over the substrate 101. The lower structure 102 may include, for example, a transistor having a gate dielectric layer and a gate electrode. Also, the lower structure 102 may include a lower interconnection for coupling the metal interconnections 103 to the substrate 101. The lower structure 102 may include a lower inter-layer dielectric layer.

The metal interconnections 103 may be uppermost-layer metal interconnections of multi-level metal interconnections. The metal interconnections 103 may include, for example, aluminum (Al). The metal interconnections 103 may be a ReDistribution Layer (RDL).

The metal interconnections 103 may be disposed to be spaced apart in a first direction parallel to a top surface of the lower structure 102. Each of the metal interconnections 103 may have a rectangular side cross section extending in a second direction vertically above the top surface of the lower structure 102. Each of the metal interconnections 103 may also extend in a third direction that is parallel to the top surface of the lower structure 102 and perpendicular to the first and second directions. The dimensions of the metal interconnections in the first, second, and third directions may vary by design.

The first hydrogen-containing layer 104 may cover the profile including the metal interconnections 103. The first hydrogen-containing layer 104 may directly contact the metal interconnections 103. The first hydrogen-containing layer 104 may have a linear shape. The first hydrogen-containing layer 104 may include a material having good step coverage. The first hydrogen-containing layer 104 may be formed linearly along both sidewalls and top surfaces of the metal interconnections 103 and the top surface of the lower structure 102 between the metal interconnections 103. The first hydrogen-containing layer 104 may serve as a hydrogen supply layer capable of directly supplying hydrogen to the metal interconnections 103 which are serving as a hydrogen path during a hydrogen passivation process. For example, during the hydrogen passivation process, hydrogen in the first hydrogen-containing layer 104 may diffuse into the surface of the substrate 101 through the metal interconnections 103 that are electrically connected to the substrate 101. For example, the surface of the substrate 101 to which hydrogen reaches may be an interface of a gate dielectric layer. Accordingly, the interface trap sites of the gate dielectric layer may be filled with diffused hydrogen to significantly reduce the interface trap density. Accordingly, the leakage current characteristic of the transistor may be improved.

The first hydrogen-containing layer 104 may include a dielectric material containing hydrogen. The first hydrogen-containing layer 104 may include an oxidizing material containing hydrogen. For example, the first hydrogen-containing layer 104 may include a high density plasma (HDP) oxide. The HDP oxide may be an oxide which is deposited by using high-density plasma, and a large amount of excited hydrogen may be generated during the process, which may improve the amount of hydrogen diffused into the substrate 101 through the metal interconnections 103.

The dielectric layer 105 may be formed over the metal interconnections 103 and may be formed to gap-fill the upper portion between the neighboring metal interconnections 103. The dielectric layer 105 may form an air gap 106 between the neighboring metal interconnections 103. The dielectric layer 105 may be formed to have a lower step coverage characteristic than the first hydrogen-containing layer 104. The dielectric layer 105 may cover the first hydrogen-containing layer 104. The dielectric layer 105 may include silicon oxide. For example, the dielectric layer 105 may include tetraethyl orthosilicate (TEOS) oxide.

The second hydrogen-containing layer 107 may be formed over the dielectric layer 105. The second hydrogen-containing layer 107 may include a dielectric material having a relatively high hydrogen supply capability compared to the dielectric layer 105. The second hydrogen-containing layer 107 may include a dielectric material that may function as a hydrogen source. The second hydrogen-containing layer 107 may include the same material as the first hydrogen-containing layer 104. For example, the second hydrogen-containing layer 107 may include an HDP oxide. According to an embodiment of the present invention, the second hydrogen-containing layer 107 may include a material having a higher hydrogen content in the film than the first hydrogen-containing layer 104. The second hydrogen-containing layer 107 may be referred to as a ‘hydrogen passivation layer’ or a ‘hydrogen supply layer’. When hydrogen is supplied through the hydrogen supply layer, compared to annealing in the atmosphere of hydrogen gas, it may be less affected due to the films that block the diffusion of hydrogen.

A passivation layer 110 may be further formed over the second hydrogen-containing layer 107. The passivation layer 110 may serve to protect the structures that are stacked in a vertical direction from the substrate 101 and may serve as a hydrogen source together with the first and second hydrogen-containing layers 104 and 107. The passivation layer 110 may include silicon nitride.

As a comparative example, when the dielectric layer 105 is directly formed over the metal interconnections 103, the hydrogen supplied from the second hydrogen-containing layer 107 may be captured in the dielectric layer 105 and the air gap 106, or out-diffused through the air gap 106. Therefore, the amount of hydrogen diffused to the substrate 101 may decrease, thus deteriorating the refresh characteristic of the transistor.

On the other hand, according to an embodiment of the present invention, by forming the first hydrogen-containing layer 104 that directly contacts the metal interconnections 103 and covers the sides and top surfaces of the metal interconnections 103, it is possible to increase the amount of hydrogen directly supplied to the metal interconnections 103 and to facilitate the formation of a path for diffusing the hydrogen supplied from the second hydrogen-containing layer 107 to the substrate 101.

Particularly, according to an embodiment of the present invention, the air gap 106 may be applied between the metal interconnections 103 and, at the same time, the first hydrogen-containing layer 104 in direct contact with the metal interconnections 103 may be formed, thereby improving both speed characteristics of the device and refresh characteristics.

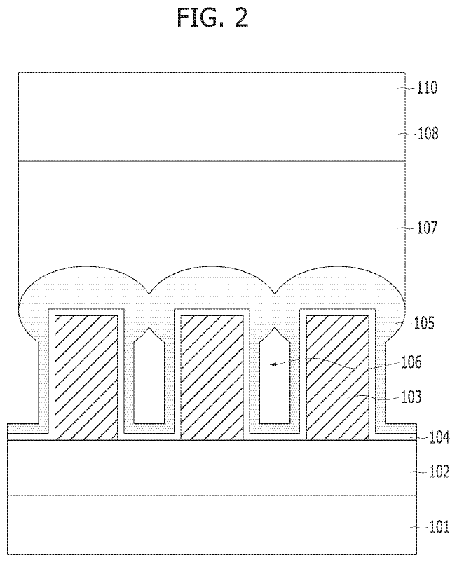

FIGS. 2 to 5 are cross-sectional views illustrating semiconductor devices in accordance with other embodiments of the present invention.

Referring to FIG. 2, a third hydrogen-containing layer 108 may be further included over the second hydrogen-containing layer 107. The third hydrogen-containing layer 108 may be formed to have a thickness similar to that of the dielectric layer 105, but the concept and spirit of the present invention are not limited thereto. The third hydrogen-containing layer 108 may be applied to secure the thickness of the hydrogen supply layer that is inevitably lowered due to the dielectric layer 105 that is essentially applied to form an air gap. The third hydrogen-containing layer 108 may include the same material as that of the second hydrogen-containing layer 107. The third hydrogen-containing layer 108 may include an HDP oxide.

A passivation layer 110 may be further formed over the third hydrogen-containing layer 108. The passivation layer 110 may serve to protect the structures that are stacked in the vertical direction from the substrate 101 and may function as a hydrogen source together with the first to third hydrogen-containing layers 104, 107, and 108. The passivation layer 110 may include silicon nitride.

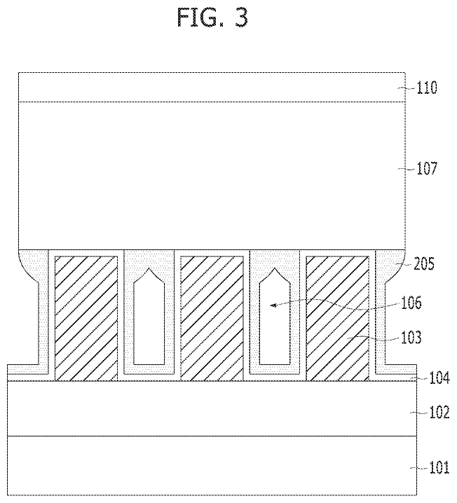

Referring to FIG. 3, a semiconductor device may include a substrate 101, a lower structure 102 formed over the substrate 101, metal interconnections 103 formed over the lower structure 102, air gaps 106 formed between the metal interconnections 103, a first hydrogen-containing layer 104 covering the metal interconnections 103, a dielectric layer 205 over the first hydrogen-containing layer 104, and a second hydrogen-containing layer 107 over the dielectric layer 205.

The first hydrogen-containing layer 104 may cover the profile including the metal interconnections 103. The first hydrogen-containing layer 104 may directly contact the metal interconnections 103. The first hydrogen-containing layer 104 may have a linear shape. The first hydrogen-containing layer 104 may include a material having good step coverage. The first hydrogen-containing layer 104 may be formed linearly along both sidewalls and top surfaces of the metal interconnections 103 and the top surface of the lower structure 102 between the metal interconnections 103. The first hydrogen-containing layer 104 may serve as a hydrogen supply layer capable of directly supplying hydrogen to the metal interconnections 103 that serve as a hydrogen path during a hydrogen passivation process. For example, during the hydrogen passivation process, hydrogen in the first hydrogen-containing layer 104 may diffuse to the surface of the substrate 101 through the metal interconnections 103 that are electrically connected to the substrate 101. For example, the surface of the substrate 101 to which hydrogen reaches may be an interface of a gate dielectric layer. Accordingly, interface trap sites of the gate dielectric layer may be filled with the diffused hydrogen to significantly reduce the interface trap density. In this way, the leakage current characteristic of the transistor may be improved.

The first hydrogen-containing layer 104 may include a dielectric material containing hydrogen. The first hydrogen-containing layer 104 may include an oxidizing material containing hydrogen. For example, the first hydrogen-containing layer 104 may include a high-density plasma (HDP) oxide. The HDP oxide may be an oxide which is deposited by using high-density plasma, and a large amount of excited hydrogen is generated during the process, which may improve the amount of hydrogen which is diffused into the substrate 101 through the metal interconnections 103.

The dielectric layer 205 may be formed to gap-fill the upper portion between the neighboring metal interconnections 103. The dielectric layer 205 may be positioned over the first hydrogen-containing layer 104 between the metal interconnections 103. The dielectric layer 205 may form the air gap 106 between the neighboring metal interconnections 103. The height of the air gap 106 may be lower than the height of the metal interconnections 103. For example, the air gap 106 may be positioned at a level lower than the top surface of the metal interconnections 103. The top surface of the dielectric layer 205 may be positioned at the same level as the top surface of the first hydrogen-containing layer 104 which is formed over the metal interconnections 103. The dielectric layer 205 may cover the first hydrogen-containing layer 104 between the metal interconnections 103. For example, the dielectric layer 205 may form the air gap 106 between the metal interconnections 103 by covering the upper portion of the first hydrogen-containing layer 104 which is formed on the sidewall of the metal interconnections 103 and the upper portion of the first hydrogen-containing layer 104 which is formed over the lower structure 102 between the neighboring metal interconnections 103, and sealing the upper portion between the neighboring metal interconnections 103.

The dielectric layer 205 may be formed to have a lower step coverage than the first hydrogen-containing layer 104. The dielectric layer 205 may cover the first hydrogen-containing layer 104. The dielectric layer 205 may include silicon oxide. For example, the dielectric layer 205 may include tetraethyl orthosilicate (TEOS) oxide.

The second hydrogen-containing layer 107 may be formed over the dielectric layer 205 and the first hydrogen-containing layer 104. The second hydrogen-containing layer 107 may directly contact the first hydrogen-containing layer 104 which is formed over the metal interconnections 103. By covering the metal interconnections 103 to form the second hydrogen-containing layer 107 in direct contact with the first hydrogen-containing layer 104 capable of supplying hydrogen, the hydrogen supplied from the second hydrogen-containing layer 107 may be directly transferred to the metal interconnections 103 without loss, thus improving the efficiency of the hydrogen path.

The second hydrogen-containing layer 107 may include a dielectric material having a relatively high hydrogen supply capability compared to the dielectric layer 205. The second hydrogen-containing layer 107 may include a dielectric material that may function as a hydrogen source. The second hydrogen-containing layer 107 may include the same material as that of the first hydrogen-containing layer 104. For example, the second hydrogen-containing layer 107 may include an HDP oxide. According to another embodiment of the present invention, the second hydrogen-containing layer 107 may include a material having a higher hydrogen content in the film than the first hydrogen-containing layer 104. The second hydrogen-containing layer 107 may be referred to as a ‘hydrogen passivation layer’ or a ‘hydrogen supply layer’. When hydrogen is supplied through the hydrogen supply layer, compared to annealing in the atmosphere of hydrogen gas, it may be less affected by the layers blocking the diffusion of hydrogen.

A passivation layer 110 may be further formed over the second hydrogen-containing layer 107. The passivation layer 110 may serve to protect the structures that are stacked in the vertical direction from the substrate 101, and may serve as a hydrogen source together with the first and second hydrogen-containing layers 104 and 107. The passivation layer 110 may include silicon nitride.

According to another embodiment of the present invention, a third hydrogen-containing layer (108, refer to FIG. 2) may be additionally formed between the second hydrogen-containing layer 107 and the passivation layer 110. The third hydrogen-containing layer 108 may include the same material as that of the second hydrogen-containing layer 107. The third hydrogen-containing layer may include an HDP oxide.

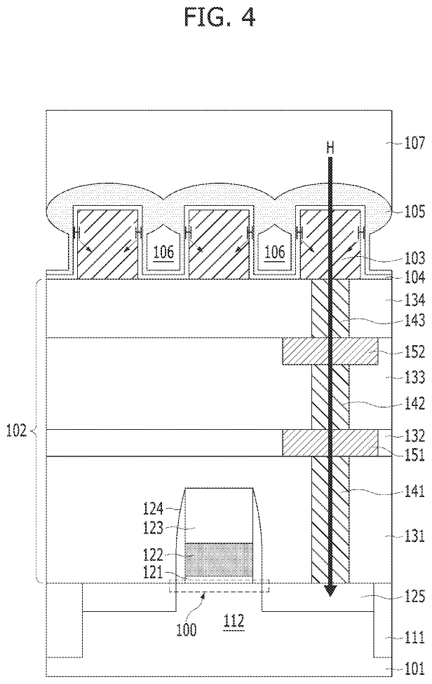

Referring to FIG. 4, the semiconductor device may include a transistor having a gate dielectric layer 121 and a gate electrode 122 and lower interconnections 151 and 152 as the lower structure 102 which is formed over the substrate 101.

The substrate 101 may include an isolation layer 111 defining the active region 112. A transistor including a stacked structure of the gate dielectric layer 121, the gate electrode 122 and a gate hard mask 123, and a gate spacer 124 formed on the sidewalls of the stacked structure may be formed over the active region 112. An impurity region 125 may be formed in the substrate 101 on both sides of the of the transistor. The impurity region 125 may be referred to as a ‘source/drain region’.

A plurality of inter-layer dielectric layers 131, 132, 133, and 134 may be stacked over the substrate 101 and the transistor. The number of the stacked structure of the inter-layer dielectric layers 131, 132, 133, and 134 may be increased or decreased according to the number of the lower interconnections 151 and 152 that are formed in the lower structure 102. The inter-layer dielectric layers 131, 132, 133, and 134 may include the same material or different materials. The inter-layer dielectric layers 131, 132, 133, and 134 may be formed of one among silicon oxide, silicon nitride, and a low-k material including silicon carbon and boron. In particular, the inter-layer dielectric layers 131, 132, 133, and 134 between the lower interconnections 151 and 152 may include a low-k dielectric material having a low dielectric constant.

Although the present embodiment shows the lower interconnections 151 and 152 of two levels, the concept and spirit of the present invention are not limited thereto, and the number of the interconnections may be increased or decreased, as necessary. The lower interconnections 151 and 152 may include a conductive material. The lower interconnections 151 and 152 may include, for example, a metal material such as tungsten or copper.

The metal interconnection 103 may be electrically connected to the substrate 101 through the lower interconnections 151 and 152. The metal interconnection 103, the lower interconnections 151 and 152, and the substrate 101 may be electrically connected by the lower contacts 141, 142, and 143. The number of the lower contacts 141, 142, and 143 may be increased and decreased according to the number of the lower interconnections 151 and 152. Some of the lower contacts 141, 142, and 143 may be simultaneously formed with some of the lower interconnections 151 and 152 through a damascene process. The lower contacts 141, 142, and 143 may include a conductive material. The lower contacts 141, 142, and 143 may include polysilicon or a metal material such as tungsten and copper.

The metal interconnections 103 formed over the lower structure 102, the air gap 106 between the metal interconnections 103, the first hydrogen-containing layer 104 covering the metal interconnections 102, the dielectric layer 105 over the first hydrogen-containing layer 104, the second hydrogen-containing layer 107 over the dielectric layer 105, and the third hydrogen-containing layer 108 over the second hydrogen-containing layer 107 may have the same structure as in FIG. 1. The concept and spirit of the present embodiment are not limited thereto, and may include the same structure as that of FIG. 2 or FIG. 3.

The metal interconnections 103 may be uppermost-layer metal interconnections of multi-level metal interconnections. The metal interconnections 103 may include, for example, aluminum (Al). The metal interconnections 103 may be a ReDistribution Layer (RDL).

The metal interconnections 103 may be disposed to be spaced apart from each other.

The first hydrogen-containing layer 104 may cover the profile including the metal interconnections 103. The first hydrogen-containing layer 104 may directly contact the metal interconnections 103. The first hydrogen-containing layer 104 may have a linear shape. The first hydrogen-containing layer 104 may include a material having good step coverage. The first hydrogen-containing layer 104 may be formed linearly along the sidewalls and top surfaces of the metal interconnections 103 and the top surface of the lower structure 102 between the metal interconnections 103. The first hydrogen-containing layer 104 may serve as a hydrogen supply layer capable of directly supplying hydrogen to the metal interconnections 103 serving as a hydrogen path during a hydrogen passivation process. For example, during the hydrogen passivation process, hydrogen in the first hydrogen-containing layer 104 may diffuse to the surface of the substrate 101 through the metal interconnections 103 that are electrically connected to the substrate 101. The surface of the substrate 101 to which hydrogen reaches may be the interface 100 of the gate dielectric layer 121. Accordingly, interface trap sites of the gate dielectric layer 121 may be filled with diffused hydrogen to significantly reduce the interface trap density. Therefore, the leakage current characteristic of the transistor may be improved.

The first hydrogen-containing layer 104 may include a dielectric material containing hydrogen. The first hydrogen-containing layer 104 may include an oxidizing material containing hydrogen. For example, the first hydrogen-containing layer 104 may include high density plasma (HDP) oxide. The HDP oxide may be an oxide which is deposited by using high-density plasma, and a large amount of excited hydrogen may be generated during the process, which may improve the amount of hydrogen diffused to the substrate 101 through the metal interconnections 103.

The dielectric layer 105 may be formed over the metal interconnections 103 and may be formed to gap-fill the upper portion between the neighboring metal interconnections 103. The dielectric layer 105 may form the air gap 106 between the neighboring metal interconnections 103. The dielectric layer 105 may be formed to have a lower step coverage than the first hydrogen-containing layer 104. The dielectric layer 105 may cover the first hydrogen-containing layer 104. The dielectric layer 105 may include silicon oxide. For example, the dielectric layer 105 may include tetraethyl orthosilicate (TEOS) oxide.

The second hydrogen-containing layer 107 may be formed over the dielectric layer 105. The second hydrogen-containing layer 107 may include a dielectric material having a relatively high hydrogen supply capability compared to the dielectric layer 105. The second hydrogen-containing layer 107 may include a dielectric material that may function as a hydrogen source. The second hydrogen-containing layer 107 may include the same material as that of the first hydrogen-containing layer 104. For example, the second hydrogen-containing layer 107 may include an HDP oxide. According to another embodiment of the present invention, the second hydrogen-containing layer 107 may include a material having a higher hydrogen content in the film than that of the first hydrogen-containing layer 104. The second hydrogen-containing layer 107 may be referred to as a ‘hydrogen passivation layer’ or a ‘hydrogen supply layer’. When hydrogen is supplied through the hydrogen supply layer, compared to annealing in the atmosphere of hydrogen gas, it may be less affected by the layers blocking the diffusion of hydrogen.

A passivation layer (110, refer to FIG. 1) may be further formed over the second hydrogen-containing layer 107. The passivation layer may serve to protect the structures that are stacked in the vertical direction from the substrate 101, and may serve as a hydrogen source together with the first and second hydrogen-containing layers 104 and 107. The passivation layer may include silicon nitride.

According to another embodiment of the present invention, a third hydrogen-containing layer (108, refer to FIG. 2) may be additionally formed between the second hydrogen-containing layer 107 and the passivation layer (110, refer to FIG. 1). The third hydrogen-containing layer may include the same material as the second hydrogen-containing layer 107. The third hydrogen-containing layer may include an HDP oxide.

As a comparative example, when the dielectric layer 105 is directly formed on the metal interconnections 103, the hydrogen supplied from the second hydrogen-containing layer 107 may be captured in the dielectric layer 105 and the air gap 106 or out-diffused through the air gap 106. Thus, the amount of hydrogen diffused to the substrate 101 may decrease, thereby deteriorating the refresh characteristic of the transistor.

On the contrary, according to an embodiment of the present invention, by forming the first hydrogen-containing layer 104 that directly contacts the metal interconnections 103 and covers the sides and top surfaces of the metal interconnections 103, it is possible to increase the amount of hydrogen which is directly supplied to the metal interconnections 103 and to facilitate the formation of a path for diffusing the hydrogen supplied from the second hydrogen-containing layer 107 to the substrate 101.

Particularly, according to an embodiment of the present invention, by forming the first hydrogen-containing layer 104 in direct contact with the metal interconnections 103 while applying the air gap 106 between the metal interconnections 103 at the same time, it is possible to improve both speed characteristics and refresh characteristics of a device.

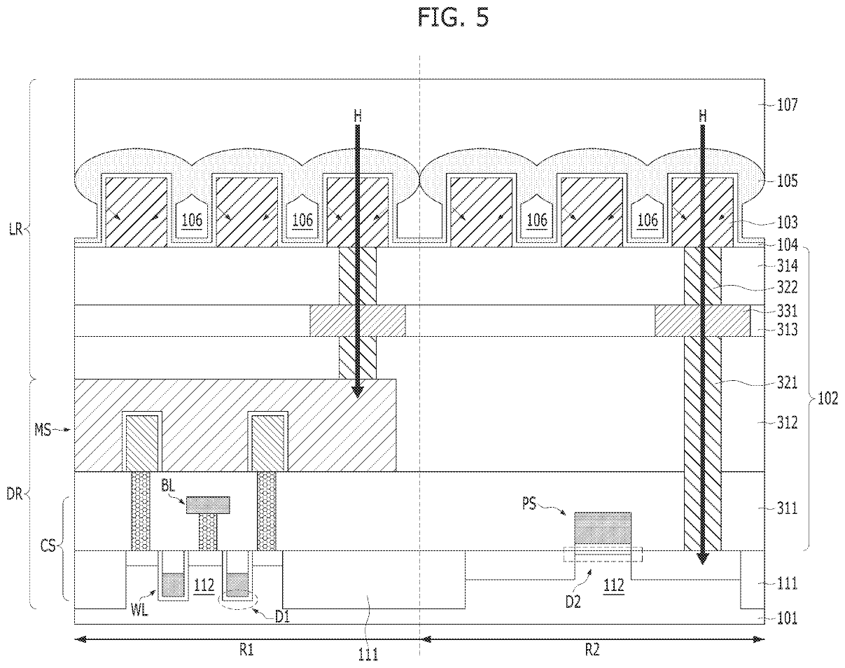

Referring to FIG. 5, the semiconductor device may include a device region DR and an interconnection region LR. The device region DR may be a region including the substrate 101 and a plurality of transistors formed thereon. When the semiconductor device of the present invention is a memory device, the device region DR may include a cell array region R1 and a peripheral circuit region R2 for driving the cell array region R1. The cell array region R1 may be a region where memory cells are disposed. The peripheral circuit region R2 may be a region where a word line driver, a sense amplifier, row and column decoders, and control circuits are disposed. When the semiconductor device according to an embodiment of the present invention is a non-memory device, the device region DR may not include the cell array region R1.

The semiconductor device may include a device region DR which is formed in a cell array region R1, a peripheral transistor region PS which is formed in a peripheral circuit region R2, inter-layer dielectric layers 311, 312, 313, and 314 which cover the device region DR and the peripheral transistor region PS, and lower interconnections 331 which electrically connect the substrate 101 to the metal interconnection 103 by penetrating the inter-layer dielectric layers 311, 312, 313, and 314 as the lower structure 102 formed over the substrate 101.

The cell array region R1 may include a cell transistor region CS and a memory structure MS over the cell transistor region CS. When the semiconductor memory device of the present invention is a DRAM device, the memory structure MS may include capacitors. The capacitors may include a stacked structure of a lower electrode, a dielectric layer, and an upper electrode.

A cell transistor region CS may include unit memory cells formed of an active region 112 defined by the isolation layer 111, word lines WL formed in the active region 112, and bit lines BL formed over the active region 112. A plurality of impurity regions that are separated from each other by the word lines WL may be provided in the active region 112. From the perspective of a plan view, the bit lines BL may extend in a direction crossing the word lines WL. The bit lines BL may be electrically connected to the substrate 101 through a bit line contact. The capacitors may be electrically connected to the substrate 101 through a storage node contact. Although the present embodiment is described taking an example of a Dynamic Random Access Memory (DRAM), the semiconductor memory device according to an embodiment of the present invention is not limited to a DRAM, and it may be a memory device including a variable resistor such as a phase change material.

The peripheral circuit region R2 may include the peripheral transistor region PS. The peripheral transistor region PS may include the active region 112 defined by the isolation layer 111 and a transistor formed over the active region 112.

A plurality of inter-layer dielectric layers 311, 312, 313, and 314 may be stacked over the substrate 101, the cell transistor region CS, and the peripheral transistor region PS of the cell array region R1 and the peripheral circuit region R2. The stacked structure of the inter-layer dielectric layers 311, 312, 313, and 314 may be increased or decreased according to the number of the lower interconnections 331 formed in the lower structure 102. The inter-layer dielectric layers 311, 312, 313, and 314 may include the same material or different materials. The inter-layer dielectric layers 311, 312, 313, and 314 may be formed of one among silicon oxide, silicon nitride, or a low-k material including silicon carbon and boron. In particular, the inter-layer dielectric layer 314 between the lower interconnection 331 and the metal interconnections 103 may include a low-k dielectric material having a low dielectric constant.

Although this embodiment shows the lower interconnections 331 of one level, the concept and spirit of the present invention are not limited thereto, and the number of the interconnections may be increased or decreased, as necessary. The lower interconnections 331 may include a conductive material. The lower interconnections 331 may include, for example, a metal material such as tungsten or copper.

The metal interconnection 103 according to an embodiment of the present invention may be electrically connected to the substrate 101 through the lower interconnections 331. The metal interconnections 103, the lower interconnections 331, and the substrate 101 may be electrically connected by lower contacts 321 and 322. The number of the lower contacts 321 and 322 may be increased or decreased according to the number of the lower interconnections 331. The lower contacts 321 and 322 may include a conductive material. The lower contacts 321 and 322 may include polysilicon or a metal material such as tungsten and copper.

The metal interconnections 103 formed in the upper portion of the lower structure 102, the air gap 106 between the metal interconnections 103, the first hydrogen-containing layer 104 covering the metal interconnections 103, the dielectric layer 105 over the first hydrogen-containing layer 104, the second hydrogen-containing layer 107 over the dielectric layer 105, and the third hydrogen-containing layer 108 over the second hydrogen-containing layer 107 may have the same structure as shown in FIG. 1. However, the concept and spirit of the embodiment of the present invention are not limited thereto, and may include the same structure as that of FIG. 2 or FIG. 3.

Although the embodiment of the present invention illustrates a case where the metal interconnection 103 is included in each of the cell array region R1 and the peripheral circuit region R2, according to another embodiment of the present invention, the metal interconnection 103 may be applied to only one region among the cell array region R1 and the peripheral circuit region R2. According to another embodiment of the present invention, the metal interconnections 103 formed in each of the cell array region R1 and the peripheral circuit region R2 may be positioned at different levels.

The metal interconnections 103 may be uppermost-layer metal interconnections of multi-level metal interconnections. The metal interconnections 103 may include, for example, aluminum (Al). The metal interconnections 103 may be a ReDistribution Layer (RDL).

The metal interconnections 103 may be disposed to be spaced apart from each other.

The first hydrogen-containing layer 104 may cover the profile including the metal interconnections 103. The first hydrogen-containing layer 104 may directly contact the metal interconnections 103. The first hydrogen-containing layer 104 may have a linear shape. The first hydrogen-containing layer 104 may include a material having good step coverage. The first hydrogen-containing layer 104 may be formed linearly along both sidewalls and the top surfaces of the metal interconnections 103 and the top surface of the lower structure 102 between the metal interconnections 103. The first hydrogen-containing layer 104 may serve as a hydrogen supply layer capable of directly supplying hydrogen to the metal interconnections 103 which serve as a hydrogen path during a hydrogen passivation process. For example, during the hydrogen passivation process, hydrogen in the first hydrogen-containing layer 104 may diffuse into the surface of the substrate 101 through the metal interconnections 103 that are electrically connected to the substrate 101. The surface of the substrate 101 to which hydrogen reaches may be an interface D1 of the gate dielectric layer that forms the word line WL in the cell array region R1 and an interface D2 between the peripheral transistor region PS and the substrate 101 in the peripheral circuit region R2. Accordingly, trap sites of each of the interfaces D1 and D2 may be filled with diffused hydrogen to significantly decrease the interface trap density. As a result, the leakage current characteristic of the transistor may be improved.

The first hydrogen-containing layer 104 may include a dielectric material containing hydrogen. The first hydrogen-containing layer 104 may include an oxidizing material containing hydrogen. For example, the first hydrogen-containing layer 104 may include high density plasma (HDP) oxide. The HDP oxide may be an oxide which is deposited by using high-density plasma, and a large amount of excited hydrogen may be generated during the process, which may improve the amount of hydrogen diffused to the substrate 101 through the metal interconnections 103.

The dielectric layer 105 may be formed over the metal interconnections 103 to gap-fill the upper portion between the neighboring metal interconnections 103. The dielectric layer 105 may form the air gap 106 between the neighboring metal interconnections 103. The dielectric layer 105 may be formed to have a lower step coverage than the first hydrogen-containing layer 104. The dielectric layer 105 may cover the first hydrogen-containing layer 104. The dielectric layer 105 may include silicon oxide. For example, the dielectric layer 105 may include tetraethyl orthosilicate (TEOS) oxide.

The second hydrogen-containing layer 107 may be formed over the dielectric layer 105. The second hydrogen-containing layer 107 may include a dielectric material having a relatively high hydrogen supply capability, compared to the dielectric layer 105. The second hydrogen-containing layer 107 may include a dielectric material that may function as a hydrogen source. The second hydrogen-containing layer 107 may include the same material as that of the first hydrogen-containing layer 104. For example, the second hydrogen-containing layer 107 may include an HDP oxide. According to another embodiment of the present invention, the second hydrogen-containing layer 107 may include a material having a higher hydrogen content in the film than the first hydrogen-containing layer 104. The second hydrogen-containing layer 107 may be referred to as a ‘hydrogen passivation layer’ or a ‘hydrogen supply layer’. When hydrogen is supplied through the hydrogen supply layer, it may be less affected by the layers blocking the diffusion of hydrogen, compared to annealing in the atmosphere of hydrogen gas.

A passivation layer (110, refer to FIG. 1) may be further formed over the second hydrogen-containing layer 107. The passivation layer may serve to protect the structures that are stacked in the vertical direction from the substrate 101, and may serve as a hydrogen source together with the first and second hydrogen-containing layers 104 and 107. The passivation layer may include silicon nitride.

According to another embodiment of the present invention, a third hydrogen-containing layer (108, refer to FIG. 2) may be additionally formed between the second hydrogen-containing layer 107 and the passivation layer (110, refer to FIG. 1). The third hydrogen-containing layer may include the same material as that of the second hydrogen-containing layer 107. The third hydrogen-containing layer may include an HDP oxide.

As a comparative example, when the dielectric layer 105 is directly formed over the metal interconnections 103, hydrogen supplied from the second hydrogen-containing layer 107 may be captured in the dielectric layer 105 and the air gap 106 or out-diffused through the air gap 106, which may decrease the amount of hydrogen diffused to the substrate 101, thereby deteriorating the refresh characteristic of the transistor.

On the contrary, according to an embodiment of the present invention, by forming the first hydrogen-containing layer 104 that directly contacts the metal interconnections 103 and covers the sides and top surfaces of the metal interconnections 103, it is possible to increase the amount of hydrogen directly supplied to the metal interconnections 103 and to facilitate the formation of a path for diffusing the hydrogen supplied from the second hydrogen-containing layer 107 to the substrate 101.

Particularly, according to an embodiment of the present invention, it is possible to improve both speed characteristics and refresh characteristics of a device by applying the air gap 106 between the metal interconnections 103 and forming the first hydrogen-containing layer 104 in direct contact with the metal interconnections 103 at the same time.

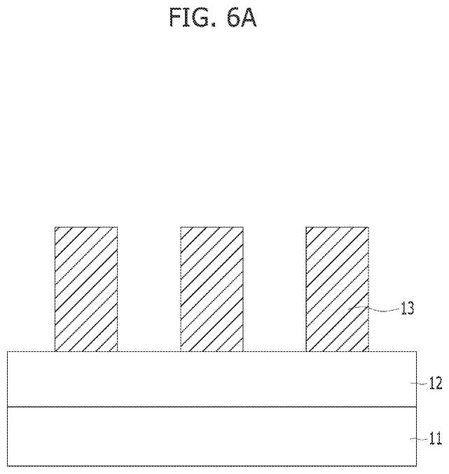

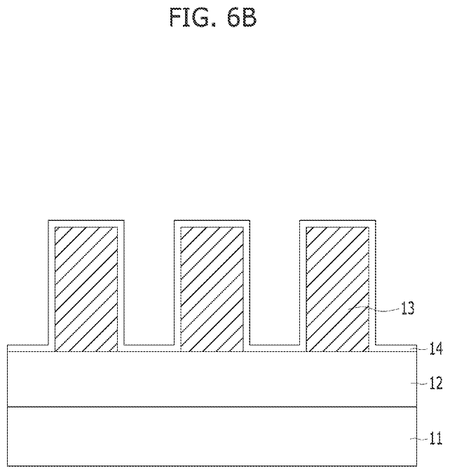

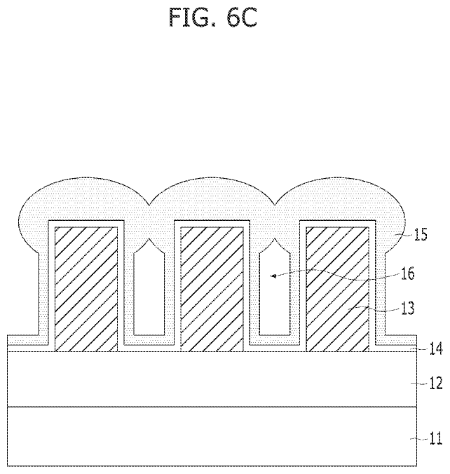

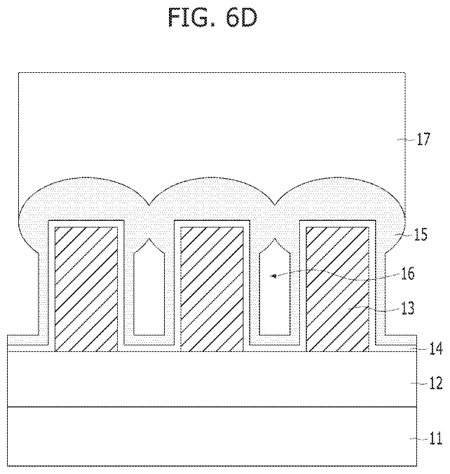

FIGS. 6A to 6D are cross-sectional views illustrating a method for fabricating a semiconductor device in accordance with an embodiment of the present invention.

Referring to FIG. 6A, a lower structure 12 may be formed over the substrate 11.

The substrate 11 may be a material suitable for semiconductor processing. The substrate 11 may include a semiconductor substrate. The substrate 11 may be formed of a material containing silicon. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may include other semiconductor materials, such as germanium. The substrate 11 may include a III/V-group semiconductor substrate, for example, a compound substrate, such as GaAs. The substrate 11 may include a Silicon-On-Insulator (SOI) substrate.

The lower structure 12 may be formed over the substrate 11, and the lower structure 12 may include, for example, a transistor, a capacitor, a lower interconnection, and a lower inter-layer dielectric layer. The lower structure 12 may include the lower structure 102 shown in FIG. 4 or FIG. 5.

The metal interconnections 13 may be uppermost-layer metal interconnections of multi-level metal interconnections. For example, when the multi-level metal interconnection is formed in three layers, the first and second metal interconnections may be included in the lower structure 12, and the metal interconnections 13 of the embodiment of the present invention may represent the third metal interconnection, which is the uppermost layer. The metal interconnections 13 may include, for example, aluminum (Al). The formation of the metal interconnections 13 may include formation of a conductive layer and a patterning process. Each of the metal interconnections 13 may be disposed to be spaced apart from each other at regular intervals.

Referring to FIG. 6B, a first hydrogen-containing layer 14 may be formed on the profile including the metal interconnections 13.

The first hydrogen-containing layer 14 may cover the profile including the metal interconnections 13. The first hydrogen-containing layer 14 may directly contact the metal interconnections 13. The first hydrogen-containing layer 14 may have a linear shape. The first hydrogen-containing layer 14 may include a material having good step coverage. The first hydrogen-containing layer 14 may be formed linearly along both sidewalls and the top surfaces of the metal interconnections 13 and the top surface of the lower structure 12 between the metal interconnections 13. The first hydrogen-containing layer 14 may serve as a hydrogen supply layer capable of directly supplying hydrogen to the metal interconnections 13 that serves as a hydrogen path during a hydrogen passivation process. For example, during the hydrogen passivation process, hydrogen in the first hydrogen-containing layer 14 may be diffused to the surface of the substrate 11 through the metal interconnections 13 that are electrically connected to the substrate 11. For example, the surface of the substrate 11 to which hydrogen reaches may be an interface of a gate dielectric layer. Accordingly, interface trap sites of the gate dielectric layer may be filled with diffused hydrogen to significantly decrease the interface trap density. Therefore, the leakage current characteristic of a transistor may be improved.

The first hydrogen-containing layer 14 may include a dielectric material containing hydrogen. The first hydrogen-containing layer 14 may include an oxidizing material containing hydrogen. For example, the first hydrogen-containing layer 14 may include high density plasma (HDP) oxide. The HDP oxide may be an oxide which is deposited by using high-density plasma, and a large amount of excited hydrogen may be generated during the process, which may improve the amount of hydrogen diffused into the substrate 11 through the metal interconnections 13 can be improved.

Referring to FIG. 6C, a dielectric layer 15 may be formed over the first hydrogen-containing layer 14.

The dielectric layer 15 may gap-fill the upper portion between the neighboring metal interconnections 13 to provide an air gap 16 between the metal interconnections 13. The dielectric layer 15 may be formed to have a lower step coverage than the first hydrogen-containing layer 14. The dielectric layer 15 may cover the first hydrogen-containing layer 14. The dielectric layer 15 may include silicon oxide. For example, the dielectric layer 15 may include tetraethyl orthosilicate (TEOS) oxide.

The top surface of the dielectric layer 15 may be positioned at a higher level than the top surface of the first hydrogen-containing layer 14 over the metal interconnections 13.

Referring to FIG. 6D, a second hydrogen-containing layer 17 may be formed over the dielectric layer 15.

The second hydrogen-containing layer 17 may include a dielectric material having a relatively high hydrogen supply capability, compared to the dielectric layer 15. The second hydrogen-containing layer 17 may include a dielectric material that may function as a hydrogen source. The second hydrogen-containing layer 17 may include the same material as that of the first hydrogen-containing layer 14. For example, the second hydrogen-containing layer 17 may include an HDP oxide. According to another embodiment of the present invention, the second hydrogen-containing layer 17 may include a material having a higher hydrogen content in the film than the first hydrogen-containing layer 14. The second hydrogen-containing layer 17 may be referred to as a ‘hydrogen passivation layer’ or a ‘hydrogen supply layer’.

Subsequently, a passivation layer may be further formed over the second hydrogen-containing layer 17. The passivation layer may serve to protect the structures that are stacked in the vertical direction from the substrate 11, and may serve as a hydrogen source together with the first and second hydrogen-containing layers 14 and 17. The passivation layer may include silicon nitride.

According to another embodiment of the present invention, a third hydrogen-containing layer (108, refer to FIG. 2) may be additionally formed between the second hydrogen-containing layer 17 and the passivation layer. The third hydrogen-containing layer may be formed to have a thickness similar to that of the dielectric layer 15, but the concept and spirit of the present invention are not limited thereto. The third hydrogen-containing layer may be applied to secure the thickness of the hydrogen supply layer which is inevitably decreased due to the dielectric layer 15 that is essentially applied to form an air gap. The third hydrogen-containing layer may include the same material as that of the second hydrogen-containing layer 17. The third hydrogen-containing layer may include an HDP oxide.

Subsequently, an alloy process may be performed. The alloy process may refer to a heat treatment process for supplying hydrogen in the hydrogen supply layer which includes the first and second hydrogen-containing layers 14 and 17 to the surface of the substrate 101. The alloy process may supply hydrogen to the interface between the substrate 101 and the transistor from the first and second hydrogen-containing layers 14 and 17. The alloy process may be performed in the atmosphere of hydrogen or deuterium.

As described above, according to an embodiment of the present invention, the hydrogen passivation effect may be improved by additionally forming the first hydrogen-containing layer 104 capable of supplying hydrogen directly to the metal interconnections 103 which serve as a hydrogen path during a hydrogen passivation process. Also, according to an embodiment of the present invention, both speed characteristics and refresh characteristics of a device may be improved by forming a hydrogen path while applying the air gap 16 between the metal interconnections 13.

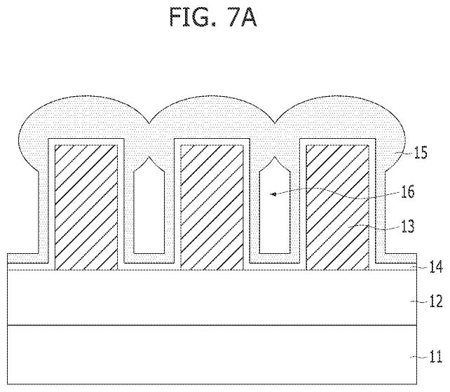

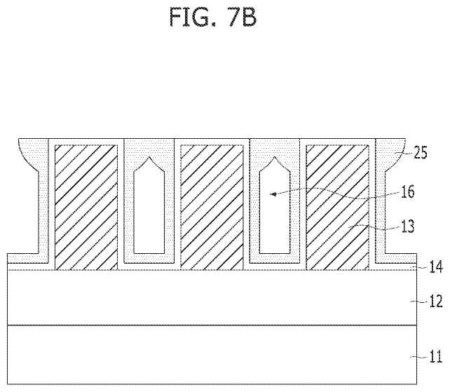

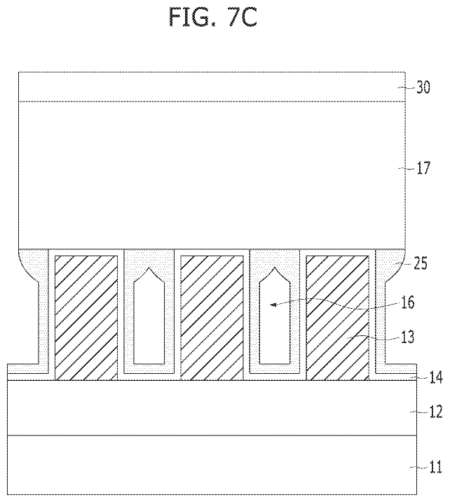

FIGS. 7A to 7C are cross-sectional views illustrating another example of a method for fabricating a semiconductor device in accordance with an embodiment of the present invention. FIG. 7A shows the same structure as FIG. 6C. The process of forming the structure of FIG. 7A may be performed in the same manner as shown in FIGS. 6A and 6B.

Referring to FIGS. 7A and 7B, a dielectric layer 15 may be formed over the first hydrogen-containing layer 14.

The dielectric layer 15 may gap-fill the upper portion between the neighboring metal interconnections 13 to provide an air gap 16 between the metal interconnections 13. The dielectric layer 15 may be formed to have a lower step coverage than that of the first hydrogen-containing layer 14. The dielectric layer 15 may cover the first hydrogen-containing layer 14. The dielectric layer 15 may include silicon oxide. For example, the dielectric layer 15 may include tetraethyl orthosilicate (TEOS) oxide.

The height of the air gap 16 defined by the dielectric layer 15 may be lower than the height of the metal interconnections 13. For example, the air gap 16 may be positioned at a level lower than the top surface of the metal interconnections 13.

Subsequently, the first hydrogen-containing layer 14 over the metal interconnections 13 may then be exposed. See FIG. 7B. To this end, a planarization process may be performed onto the dielectric layer 15. The planarization process may include an etch-back process or a Chemical Mechanical Polishing (CMP) process.

The etched dielectric layer may be referred to as a dielectric pattern 25. The top surface of the dielectric pattern 25 may be positioned at the same level as the top surface of the first hydrogen-containing layer 14 over the metal interconnections 13.

Referring to FIG. 7C, a second hydrogen-containing layer 17 may be formed over the dielectric pattern 25. The second hydrogen-containing layer 17 may directly contact the first hydrogen-containing layer 14 which is formed over the metal interconnections 13.

The second hydrogen-containing layer 17 may include a dielectric material having a relatively high hydrogen supply capability, compared to the dielectric pattern 25. The second hydrogen-containing layer 17 may include a dielectric material that may function as a hydrogen source. The second hydrogen-containing layer 17 may include the same material as the first hydrogen-containing layer 14. For example, the second hydrogen-containing layer 17 may include an HDP oxide. According to another embodiment of the present invention, the second hydrogen-containing layer 17 may include a material having a higher hydrogen content in the film than the first hydrogen-containing layer 14. The second hydrogen-containing layer 17 may be referred to as a ‘hydrogen passivation layer’ or a ‘hydrogen supply layer’.

Subsequently, a passivation layer 30 may be further formed over the second hydrogen-containing layer 17. The passivation layer 30 may serve to protect the structures that are stacked in the vertical direction from the substrate 11, and may serve as a hydrogen source together with the first and second hydrogen-containing layers 14 and 17. The passivation layer 30 may include silicon nitride.

According to another embodiment of the present invention, a third hydrogen-containing layer (108, refer to FIG. 2) may be additionally formed between the second hydrogen-containing layer 17 and the passivation layer 30. The third hydrogen-containing layer may be formed to have a thickness similar to that of the dielectric layer 15, but the concept and spirit of the present invention are not limited thereto. The third hydrogen-containing layer may be applied to secure the thickness of the hydrogen supply layer which is inevitably decreased due to the dielectric layer 15 that is essentially applied to form an air gap. The third hydrogen-containing layer may include the same material as that of the second hydrogen-containing layer 17. The third hydrogen-containing layer may include an HDP oxide.

Subsequently, an alloy process may be performed. The alloy process refers to a heat treatment process for supplying hydrogen in the hydrogen supply layer which includes the first and second hydrogen-containing layers 14 and 17 to the surface of the substrate 101. The alloy process may supply hydrogen to the interface between the substrate 101 and a transistor from the first and second hydrogen-containing layers 14 and 17. The alloy process may be performed in the atmosphere of hydrogen or deuterium.

As described above, according to an embodiment of the present invention, the first hydrogen-containing layer 14 capable of directly supplying hydrogen to the metal interconnections 103 which serve as a hydrogen path during a hydrogen passivation process may be additionally formed, and since the first hydrogen-containing layer 14 is formed in direct contact with the second hydrogen-containing layer 17, the hydrogen supplied from the second hydrogen-containing layer 17 may be directly transferred to the metal interconnections 13 without loss, which may improve the efficiency of the hydrogen path. Also, according to an embodiment of the present invention, both speed characteristics and refresh characteristics of the device may be improved by forming a hydrogen path while applying the air gap 16 between the metal interconnections 13.

According to an embodiment of the present invention, speed characteristics and power competitiveness of a device may be secured by applying an air gap between metal interconnections.

According to an embodiment of the present invention, leakage current characteristics of a device may be improved by increasing the efficiency of hydrogen passivation, thereby securing reliability.

The effects desired to be obtained in the embodiments of the present invention are not limited to the effects mentioned above, and other effects not mentioned above may also be clearly understood by those of ordinary skill in the art to which the present invention pertains from the description below.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a plurality of metal interconnections spaced apart over a substrate including a lower structure;
a first hydrogen-containing layer covering the plurality of the metal interconnections;
a dielectric layer formed over the first hydrogen-containing layer;
an air gap formed between neighboring metal interconnections inside the dielectric layer; and
a second hydrogen-containing layer formed over the dielectric layer.

2. The semiconductor device of claim 1, wherein the first hydrogen-containing layer is in direct contact with both sidewalls and a top surface of each of the metal interconnections.

3. The semiconductor device of claim 1, wherein the first hydrogen-containing layer is formed linearly along the plurality of the metal interconnections.

4. The semiconductor device of claim 1, wherein the first hydrogen-containing layer and the second hydrogen-containing layer are dielectric materials including hydrogen.

5. The semiconductor device of claim 1, wherein the first and second hydrogen-containing layers include High Density Plasma (HDP) oxide.

6. The semiconductor device of claim 1, wherein a top surface of the dielectric layer is positioned at a higher level than a top surface of the first hydrogen-containing layer which is formed over the plurality of the metal interconnections.

7. The semiconductor device of claim 1, wherein the dielectric layer is formed to have a lower step coverage than the first hydrogen-containing layer.

8. The semiconductor device of claim 1, wherein the dielectric layer includes tetraethyl orthosilicate (TEOS) oxide.

9. The semiconductor device of claim 1, further comprising:
a passivation layer over the second hydrogen-containing layer.

10. The semiconductor device of claim 9, wherein the passivation layer includes silicon nitride.

11. The semiconductor device of claim 1, wherein the lower structure includes a transistor, and the transistor is electrically connected to at least one of the plurality of the metal interconnections.

12. A semiconductor device, comprising:
a plurality of metal interconnections that are spaced apart over a substrate including a lower structure;
a first hydrogen-containing layer covering the plurality of the metal interconnections;
a dielectric layer formed over the first hydrogen-containing layer between the metal interconnections and including an air gap; and
a second hydrogen-containing layer formed over the dielectric layer and the first hydrogen-containing layer.

13. The semiconductor device of claim 12, wherein the air gap is positioned at a lower level than top surfaces of the plurality of the metal interconnections.

14. The semiconductor device of claim 12, wherein the first hydrogen-containing layer is formed linearly along the plurality of the metal interconnections.

15. The semiconductor device of claim 12, wherein the first hydrogen-containing layer and the second hydrogen-containing layer are dielectric materials including hydrogen.

16. The semiconductor device of claim 12, wherein the first and second hydrogen-containing layers include High Density Plasma (HDP) oxide.

17. The semiconductor device of claim 12, wherein the dielectric layer is formed to have a lower step coverage than the first hydrogen-containing layer.

18. The semiconductor device of claim 12, wherein the dielectric layer includes tetraethyl orthosilicate (TEOS) oxide.

19. The semiconductor device of claim 12, further comprising:
a passivation layer over the second hydrogen-containing layer.

20. The semiconductor device of claim 19, wherein the passivation layer includes silicon nitride.

21. The semiconductor device of claim 12, wherein the lower structure includes a transistor, and the transistor is electrically connected to at least one of the metal interconnections.

22. A method for fabricating a semiconductor device, comprising:
forming a plurality of metal interconnections spaced apart over a substrate including a lower structure;
forming a first hydrogen-containing layer which covers the plurality of the metal interconnections;
forming a dielectric layer including an air gap over the first hydrogen-containing layer; and
forming a second hydrogen-containing layer over the dielectric layer.

23. The method of claim 22, further comprising:
performing a heat treatment for supplying hydrogen to a surface of the substrate.

24. The semiconductor device of claim 22, wherein the first hydrogen-containing layer is formed linearly along the plurality of the metal interconnections.

25. The method of claim 22, further comprising:
etching the dielectric layer to expose the first hydrogen-containing layer that covers top surfaces of the plurality of the metal interconnections, after the forming of the dielectric layer.

26. The method of claim 22, wherein the dielectric layer is formed to have a lower step coverage than the first hydrogen-containing layer.

27. The method of claim 22, wherein the dielectric layer includes tetraethyl orthosilicate (TEOS) oxide.

28. The method of claim 22, wherein the first and second hydrogen-containing layers include High Density Plasma (HDP) oxide.

29. The method of claim 23, wherein the heat treatment process is performed in an atmosphere of hydrogen or deuterium.

30. The method of claim 22, further comprising:
after the forming of the second hydrogen-containing layer,
forming a third hydrogen-containing layer over the second hydrogen-containing layer; and
performing a heat treatment for supplying hydrogen to a surface of the substrate.

31. The method of claim 30, wherein the third hydrogen-containing layer includes the same material as a material of the second hydrogen-containing layer.

32. The method of claim 30, wherein the third hydrogen-containing layer includes HDP oxide.

33. The method of claim 22, further comprising:
after the forming of the second hydrogen-containing layer,
forming a passivation layer over the second hydrogen-containing layer; and
performing a heat treatment for supplying hydrogen to a surface of the substrate.

34. The method of claim 33, wherein the passivation layer includes silicon nitride.

35. The method of claim 22, further comprising:
after the forming of the second hydrogen-containing layer,
forming a third hydrogen-containing layer over the second hydrogen-containing layer;
forming a passivation layer over the third hydrogen-containing layer; and
performing a heat treatment for supplying hydrogen to a surface of the substrate.

36. The method of claim 35, wherein the lower structure includes a transistor, and the transistor is electrically connected to at least one of the metal interconnections.
